(19) United States
(12) Patent Application Publication
(10) Pub. No.: US 2024/0218005 A1
(43) Pub. Date: Jul. 4, 2024

(54) NOVEL COMPOUND, PRECURSOR COMPOSITION COMPRISING SAME, AND METHOD FOR PREPARING THIN FILM USING SAME

(71) Applicant: HANSOL CHEMICAL CO., LTD, Seoul (KR)

(72) Inventors: Min-Sung PARK, Daejeon (KR); Hyo-Suk KIM, Jeollabuk-do (KR); Min-Hyuk NIM, Jeollabuk-do (KR); Jang-Hyeon SEOK, Sejong-si (KR); Jung-Woo PARK, Seoul (KR)

(21) Appl. No.: 18/254,390

(22) PCT Filed: Dec. 17, 2021
(86) PCT No.: PCT/KR2021/019283

§ 371 Date: May 25, 2023

(30) Foreign Application Priority Data
Dec. 21, 2020 (KR) 10-2020-0179319

(51) Int. Cl. C07F 15/06; C23C 16/18; C23C 16/455

(52) U.S. Cl. CPC C07F 15/06; C23C 16/18; C23C 16/45553

(57) ABSTRACT

The present disclosure relates to a vapor deposition compound capable of being deposited into a thin film through vapor deposition. Specifically, the present disclosure relates to a novel compound applicable to atomic layer deposition (ALD) or chemical vapor deposition (CVD) and having excellent reactivity, volatility, and thermal stability, a precursor composition containing the novel compound, a method of forming a thin film using the precursor composition, and a thin film formed using the precursor composition.

### TECHNICAL FIELD

The present disclosure relates to a vapor deposition compound capable of being deposited into a thin film through vapor deposition. Specifically, the present disclosure relates to a novel compound applicable to atomic layer deposition (ALD) or chemical vapor deposition (CVD) and having excellent reactivity, volatility, and thermal stability, a precursor composition containing the novel compound, a method of forming a thin film using the precursor composition, and a thin film formed using the precursor composition.

### BACKGROUND ART

With semiconductor devices being highly integrated and miniaturized, the formation of metal and metal-oxide thin films with uniform thickness is becoming crucial for application to various technologies, including microelectronics, magnetic information storage, catalysts, and the like.

For the formation of metal and metal-oxide thin films, chemical vapor deposition (CVD) or atomic layer deposition (ALD) is used. In particular, atomic layer deposition, a method in which reactants are sequentially injected into and removed from a chamber, enables the formation of a desired thin film, control of compositions, and formation of a thin film with a uniform thickness. In addition, atomic layer deposition has the advantage that a thin film can be uniformly grown on a complex and sophisticated device due to excellent step coverage.

To form a thin film using atomic layer deposition, a precursor, which plays a key role, is required to have high volatility, high thermal stability, and high reactivity in a chamber. Development of precursors is being conducted by applying a variety of ligands, and typically known ligands include halogen, alkoxide, cyclopentadiene, beta-diketonate, amide, amidinate, and the like. However, most of the known precursors are solid compounds, may have low volatility or stability, or may cause problems, such as contamination of impurities occurring during thin film deposition, so continuous development of new precursors is required.

In particular, the need for late transition metal (Mn, Fe, Co, Ni, and Cu) precursors with excellent properties among the known precursors has been highlighted for several years. However, these precursors are difficult to be developed compared to other metal precursors, so the development thereof is delayed.

For example, of all the late transition metal precursors, cobalt precursors have multiple oxidation numbers ranging from −1 to +5, typically, the oxidation numbers of +2 and +3, and can form cobalt oxide and nitride thin films applied to semiconductor devices. Cobalt metal thin films can be used for electrode materials, magnetic materials, magnetic random access memories (MRAM), diluted magnetic semiconductors (DMS), perovskite materials, catalysts, photocatalysts, and the like. In addition, a cobalt metal thin film can be used as a capping layer and a copper diffusion barrier in a metal wiring process due to the high integration of semiconductor devices, and is attracting attention as a next-generation material to replace a copper metal thin film.

Typical cobalt precursors currently known include carbonyl compounds such as CCTBA (dicobalt hexacarbonyl t-butylacetylene) and Co(CO)₃(NO), cyclopentadiene compounds such as CpCo(CO)₂, beta-diketonate compounds such as Co(tmhd)₂ and Co(acac)₂, diene compounds such as Co(^{tBu2}DAD)₂, and the like. Most of these cobalt precursors are solid compounds with relatively high melting points and low stability, and may cause contamination of impurities in a thin film during thin film deposition.

In particular, CCTBA, commonly used among these cobalt precursors, has a high vapor pressure, but C and O contamination in a thin film is serious after deposition. In addition, CpCo(CO)₂, a liquid compound, has the advantage of high vapor pressure, but is degraded at a temperature of 140° C., so thermal stability is extremely low.

Thus, there is a need to develop novel late transition metal precursors with excellent properties, in which the disadvantages of such existing cobalt precursors are improved.

### Documents of Related Art

### Patent Document

(Patent Document 1) Korean Patent Application Publication No. 10-2010-0061183

(Patent Document 2) Korean Patent Application Publication No. 10-2004-0033337

(Patent Document 3) Korean Patent No. 10-1962355

(Patent Document 4) Korean Patent No. 10-2123331

### DISCLOSURE

### Technical Problem

The present disclosure has been proposed to solve the problems of the existing late transition metal precursors mentioned above, and an objective of the present disclosure is to provide a late transition metal precursor compound for thin film deposition, the transition metal precursor compound having excellent reactivity, thermal stability, and volatility.

In particular, another objective of the present disclosure is to improve volatility and thermal stability, which were the disadvantages of existing late transition metal precursors, by using an imidazoline ligand, which has not been used in the existing late transition metal precursors.

In addition, the present disclosure is to provide a method of forming a thin film using the late transition metal precursor compound and a thin film.

However, the problems to be solved by the present disclosure are not limited to the above description, and other problems can be clearly understood by those skilled in the art from the following description.

### Technical Solution

The present disclosure aims to develop a novel compound having a low melting point despite being liquid or solid, being purified at low temperatures, and having excellent volatility and thermal stability, and a precursor composition containing the same compound, by introducing an imidazoline ligand. In the present disclosure, provided is a novel precursor containing an imidazoline ligand.

One aspect of the present disclosure provides a compound represented by Formula 1,

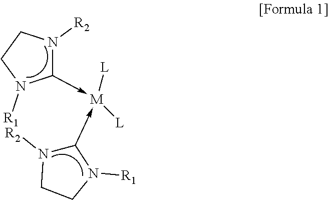

where M is Mn, Fe, Co, Ni, or Cu;
R₁ and R₂ are each independently hydrogen, or a straight-chain or branched-chain alkyl group having 1 to 4 carbon atoms;
L is —OR₃ or —NR₄R₅;
R₃ is hydrogen, or a straight-chain or branched-chain alkyl group having 1 to 4 carbon atoms; and
R₄ and R₅ are each independently hydrogen, a straight-chain or branched-chain alkyl group having 1 to 4 carbon atoms, or a straight-chain or branched-chain alkylsilyl group having 1 to 6 carbon atoms.

Another aspect of the present disclosure provides a vapor deposition precursor composition containing the compound.

A further aspect of the present disclosure provides a method of forming a thin film, the method including introducing the vapor deposition precursor composition into a chamber.

Yet a further aspect of the present disclosure provides a thin film formed using the vapor deposition precursor composition.

### Advantageous Effects

A novel compound and a precursor composition containing the novel compound, according to the present disclosure, have excellent reactivity, volatility, and thermal stability, have a low melting point despite being liquid or solid, and enable deposition of a uniform thin film with excellent properties. Thus, excellent thin film physical properties, thickness, and step coverage can be obtained.

Such physical properties provide a late transition metal precursor suitable for atomic layer deposition and chemical vapor deposition, and contribute to excellent thin film properties.

### DESCRIPTION OF DRAWINGS

FIG. 1 is nuclear magnetic resonance (NMR) data for a Co(EtMeSIm)₂(OₜBu)₂ compound in Example 1 of the present disclosure:

FIG. 2 is a thermogravimetric analysis (TGA) graph of a Co(EtMeSIm)₂(OₜBu)₂ compound in Example 1 of the present disclosure:

FIG. 3 is NMR data for a Co(iPrMeSIm)₂(O^{t}Bu)₂ compound of Example 2 in the present disclosure:

FIG. 4 is a thermogravimetric analysis (TGA) graph of a Co(iPrMeSIm)₂(O^{t}Bu)₂ compound in Example 2 of the present disclosure:

FIG. 5 is NMR data for a Co(MeMeSIm)₂(btsa)₂ compound in Example 3 of the present disclosure;

FIG. 6 is a thermogravimetric analysis (TGA) graph of a Co(MeMeSIm)₂(btsa)₂ compound in Example 3 of the present disclosure:

FIG. 7 is NMR data for a Co(iPrMeSIm)₂(btsa)₂ compound in Example 4 of the present disclosure; and

FIG. 8 is a thermogravimetric analysis (TGA) graph of a Co(iPrMeSIm)₂(btsa)₂ compound in Example 4 of the present disclosure.

### BEST MODE

Hereinafter, preferred embodiments and examples of the present disclosure will be described in detail to such an extent that those skilled in the art can easily implement the technical spirit of the present disclosure. However, the present disclosure may be embodied in many different forms and is not limited to the embodiments and examples set forth herein.

The present disclosure relates to a novel compound applicable to atomic layer deposition or chemical vapor deposition and having excellent reactivity, volatility, and thermal stability, a precursor composition containing the novel compound, a method of forming a thin film using the precursor composition, and a thin film formed using the precursor composition.

As used herein, the term “alkyl” includes straight-chain or branched-chain alkyl groups and all possible isomers thereof. For example, the alkyl group may include a methyl group (Me), an ethyl group (Et), an n-propyl group (ⁿPr), an iso-propyl group (ⁱPr), an n-butyl group (ⁿBu), a tert-butyl group (^{t}Bu), an iso-butyl group (ⁱBu), a sec-butyl group (^{sec}Bu), and isomers thereof, but may not be limited thereto.

As used herein, the term “Im” refers to an abbreviation of “imidazoline”, and the term “btsa” refers to an abbreviation of “bis(trimethylsilyl)amide]”.

One aspect of the present disclosure provides a compound represented by Formula 1.

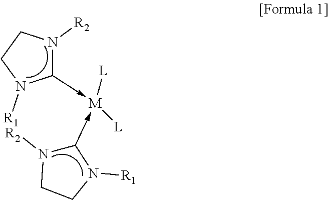

In Formula 1,
M is Mn, Fe, Co, Ni, or Cu;
R₁ and R₂ are each independently hydrogen, or a straight-chain or branched-chain alkyl group having 1 to 4 carbon atoms;
L is —OR₃ or —NR₄R₅;
R₃ is hydrogen, or a straight-chain or branched-chain alkyl group having 1 to 4 carbon atoms; and
preferably, R₄ and R₅ are each independently hydrogen, a straight-chain or branched-chain alkyl group having 1 to 4 carbon atoms, or a straight-chain or branched-chain alkylsilyl group having 1 to 6 carbon atoms.

More preferably, in one embodiment of the present disclosure, R₁, R₂, and R₃ are each independently any one selected from the group consisting of hydrogen, a methyl group, an ethyl group, an n-propyl group, an iso-propyl group, an n-butyl group, an iso-butyl group, a sec-butyl group, and a tert-butyl group, but is not limited thereto.

In one embodiment of the present disclosure, more preferably, R₄ and R₅ are each independently any one selected from the group consisting of hydrogen, a methyl group, an ethyl group, an n-propyl group, an iso-propyl group, an n-butyl group, an iso-butyl group, a sec-butyl group, a tert-butyl group, a methylsilyl group, a dimethylsilyl group, a trimethylsilyl group, and a triethylsilyl group, but is not limited thereto.

In one embodiment of the present disclosure, the compound may be liquid or solid at room temperature. The compound, according to the present disclosure, has a low melting point and excellent volatility at low temperatures.

In one embodiment of the present disclosure, the compound represented by Formula 1 may be an M(Imidazoline)(Alkoxide) compound represented by Formula 1-1.

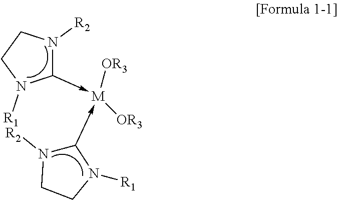

Preferably, in Formula 1-1, M is Mn, Fe, Co, Ni, or Cu; and R₁, R₂, and R₃ are each independently hydrogen, or a straight-chain or branched-chain alkyl group having 1 to 4 carbon atoms.

More preferably, for example, R₁, R₂, and R₅ are each independently any one selected from the group consisting of hydrogen, a methyl group, an ethyl group, an n-propyl group, an iso-propyl group, an n-butyl group, an iso-butyl group, a sec-butyl group, and a tert-butyl group.

In one embodiment of the present disclosure, the compound represented by Formula 1-1 may be prepared through a reaction as shown in Reaction Formula 1.

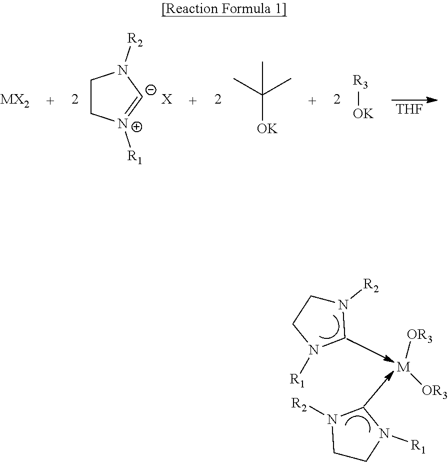

In Reaction Formula 1, M is Mn, Fe, Co, Ni, or Cu; X is a halogen element (for example, Cl, Br, or I); and R₁, R₂, and R₃ are each independently hydrogen, or a straight-chain or branched-chain alkyl group having 1 to 4 carbon atoms.

For example, examples of the M(Imidazoline)(Alkoxide) compound represented by Formula 1-1 may include the following cobalt compounds, but are not limited thereto:

Bis(1-Ethyl-3-methyl-imidazolin-2-ylidene) Cobalt di-tert-butoxide [Co(EtMeSIm)₂(O^{t}Bu)₂]; and

Bis(1-isopropyl-3-methyl-imidazolin-2-ylidene) Cobalt di-tert-butoxide [Co(iPrMeSIm)₂(O^{t}Bu)₂].

In one embodiment of the present disclosure, the compound represented by Formula 1 may be an M(Imidazoline)(Amide) compound represented by Formula 1-2.

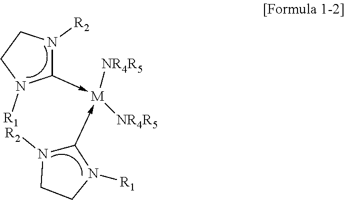

Preferably, in Formula 1-2, M is Mn, Fe, Co, Ni, or Cu; R₁ and R₂ are each independently hydrogen, or a straight-chain or branched-chain alkyl group having 1 to 4 carbon atoms, and R₄ and R₅ are each independently hydrogen, a straight-chain or branched-chain alkyl group having 1 to 4 carbon atoms, or a straight-chain or branched-chain alkylsilyl group having 1 to 6 carbon atoms.

More preferably, for example, R₁ and R₂ are each independently any one selected from the group consisting of hydrogen, a methyl group, an ethyl group, an n-propyl group, an iso-propyl group, an n-butyl group, an iso-butyl group, a sec-butyl group, and a tert-butyl group. In addition, more preferably, R₄ and R₅ are each independently any one selected from the group consisting of hydrogen, a methyl group, an ethyl group, an n-propyl group, an iso-propyl group, an n-butyl group, an iso-butyl group, a sec-butyl group, a tert-butyl group, a methylsilyl group, a dimethylsilyl group, a trimethylsilyl group, and a triethylsilyl group.

In one embodiment of the present disclosure, the compound represented by Formula 1-2 may be prepared through a reaction as shown in Reaction Formula 2.

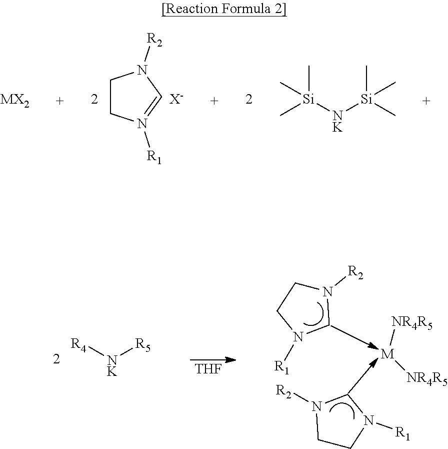

In Reaction Formula 2, M is Mn, Fe, Co, Ni, or Cu: X is a halogen element (for example, Cl, Br, or I): R₁ and R₂ are each independently hydrogen, or a straight-chain or branched-chain alkyl group having 1 to 4 carbon atoms: and R₄ and R₅ are each independently hydrogen, a straight-chain or branched-chain alkyl group having 1 to 4 carbon atoms, or a straight-chain or branched-chain alkylsilyl group having 1 to 6 carbon atoms.

For example, examples of the M(Imidazoline)(Amide) compound represented by Formula 1-2 may include the following cobalt compounds, but are not limited thereto:

Bis(1-Methyl-3-methyl-imidazolin-2-ylidene) Cobalt di-Hexamethyldisilazide [Co(MeMeSIm)₂(btsa)₂]; and

Bis(1-isopropyl-3-methyl-imidazolin-2-ylidene) Cobalt di-Hexamethyldisilazide [Co(iPrMeSIm)₂(btsa)₂].

Another aspect of the present disclosure provides a vapor deposition precursor composition containing the compound described above.

A further aspect of the present disclosure provides a method of forming a thin film, the method including introducing the vapor deposition precursor composition into a chamber. The introducing of the vapor deposition precursor into the chamber may include physical adsorption, chemical adsorption, or physicochemical adsorption.

Yet a further aspect of the present disclosure provides a thin film formed using the vapor deposition precursor composition.

All the descriptions regarding the compound may be applied to the vapor deposition precursor, the method of forming the thin film, and the thin film, according to the present disclosure. Even though detailed descriptions of overlapping parts are omitted, the omitted descriptions may be identically applied.

In one embodiment of the present disclosure, the method of forming the thin film may include both atomic layer deposition (ALD), in which the vapor deposition precursor and a reaction gas of the present disclosure are sequentially introduced, and Chemical Vapor Deposition (CVD), in which the vapor deposition precursor and a reaction gas of the present disclosure are continuously injected to form a thin film.

More specifically, the deposition method may include metal organic chemical vapor deposition (MOCVD), low-pressure chemical vapor deposition (LPCVD), pulsed-Chemical Vapor Deposition (P-CVD), plasma-enhanced atomic layer deposition (PE-ALD), or combinations thereof, but is not limited thereto.

In one embodiment of the present disclosure, the method of forming the thin film may further include injecting at least one reaction gas selected from among hydrogen (H₂), an oxygen (O) atom-containing compound (or a mixture), a nitrogen (N) atom-containing compound (or a mixture), or a silicon (Si) atom-containing compound (or a mixture).

More specifically, at least one selected from among water (H₂O), oxygen (O₂), hydrogen (H₂), ozone (O₃), ammonia (NH₃), hydrazine (N₂H₄), or silane may be used as the reaction gas. However, the reaction gas is not limited thereto.

Specifically, water (H₂O), oxygen (O₂), and ozone (O₃) may be used as the reaction gas to deposit an oxide thin film. In addition, ammonia (NH₃) or hydrazine (N₂H₄) may be used as the reaction gas to deposit a nitride thin film.

In addition, hydrogen (H₂) and silane compounds may be used as the reaction gas to deposit a metal thin film.

The thin film, formed by the thin film formation method of the present disclosure, may have a form of a metal thin film, an oxide thin film, a nitride thin film, or a silicide thin film, but is not limited thereto.

### MODE FOR INVENTION

Hereinafter, the present disclosure will be described in more detail through examples. However, the following examples are intended to explain the present disclosure in more detail, and the scope of the present disclosure is not limited by the following examples.

### Example 1: Synthesis of Co(EtMeSIm)₂(O^{t}Bu)₂

CoCl₂ (1 eq, 3 g), 1-Ethyl-3-methylimidazolium bromide (2 eq), potassium 2-butoxide (4 eq), and THF were added to a Schlenk flask and stirred overnight at room temperature. After completion of the reaction, the solvent was removed using a vacuum filter to obtain a purple liquid compound.

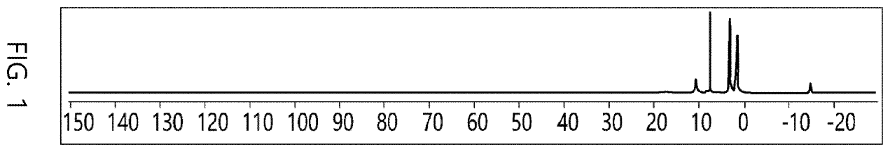

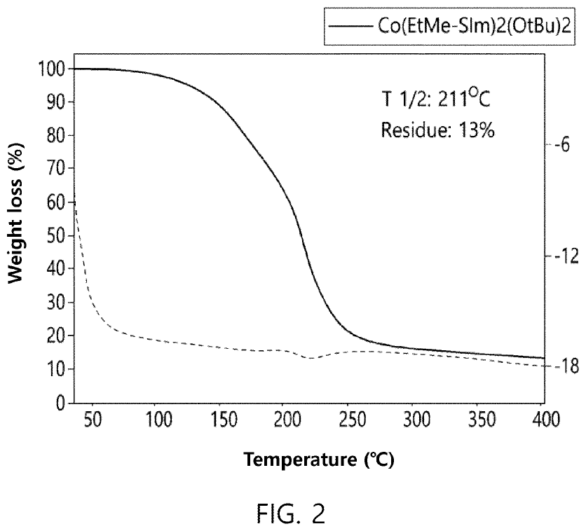

The NMR data and thermogravimetric analysis results for the compound synthesized in Example 1 are shown in FIGS. 1 and 2, respectively.

### Example 2: Synthesis of Co(iPrMeSIm)₂(O^{t}Bu)₂

CoCl₂ (1 eq, 3 g), 1-isopropyl-3-methylimidazolium bromide (2 eq), potassium 2-butoxide (4 eq), and THF were added to a Schlenk flask and stirred overnight at room temperature. After completion of the reaction, the solvent was removed using a vacuum filter to obtain a purple solid compound.

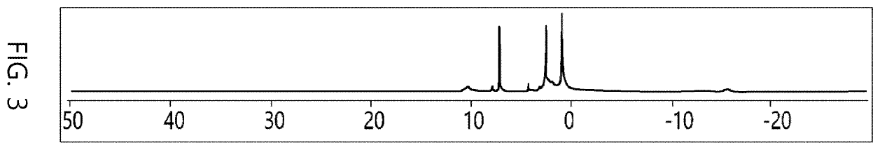

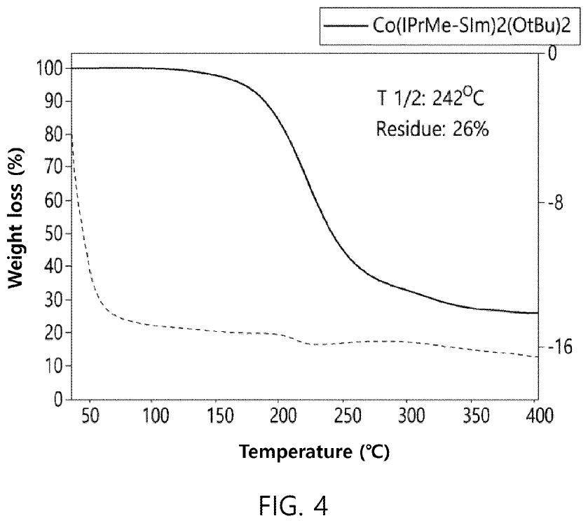

The NMR data and thermogravimetric analysis results for the compound synthesized in Example 2 are shown in FIGS. 3 and 4, respectively.

Properties of the Co(Imidazoline)(Alkoxide) compounds synthesized in Examples 1 and 2 are summarized in Table 1 below.

TABLE 1

| | Example 1 | Example 2 |
|---|---|---|
| Compound Type | Co(EtMeSIm)₂(OtBu)₂ | Co(iPrMeSIm)₂(OtBu)₂ |
| Molecular Weight | 429.51 | 457.56 |
| (M.W.) | | |
| Phase | Liquid | Solid |
| Solubility | Hexane | Hexane |
| Degradation | 198 | 232 |
| Temperature (° C.) | | |
| T_{1/2} (° C.) | 211 | 242 |

T_{1/2} in Table 1 above is the temperature at which the weight is reduced by half as a result of the thermogravimetric analysis.

### Example 3: Synthesis of Co(MeMeSIm)₂(btsa)₂

CoCl₂ (1 eq, 3 g), 1,3-dimethylimidazolium iodide (2 eq), potassium bis-trimethylsilylamide (4 eq), and THF were added to a Schlenk flask and stirred overnight at room temperature. After completion of the reaction, the solvent was removed using a vacuum filter to obtain a purple solid compound.

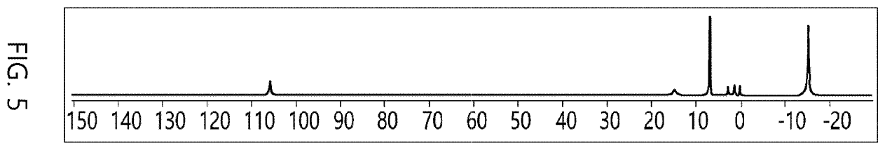

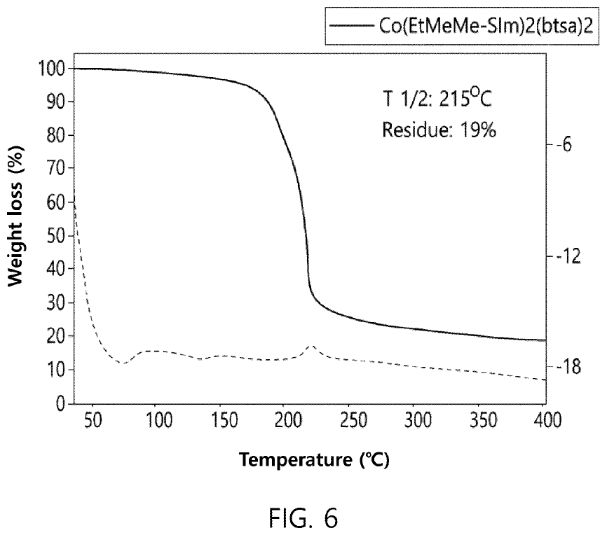

The NMR data and thermogravimetric analysis results for the compound synthesized in Example 3 are shown in FIGS. 5 and 6, respectively.

### Example 4: Synthesis of Co(iPrMeSIm)₂(btsa)₂

CoCl₂ (1 eq, 3 g), 1-isopropyl-3-methylimidazolium bromide (2 eq), potassium bis-trimethylsilylamide (4 eq), and THF were added to a Schlenk flask and stirred overnight at room temperature. After completion of the reaction, the solvent was removed using a vacuum filter to obtain a purple liquid compound.

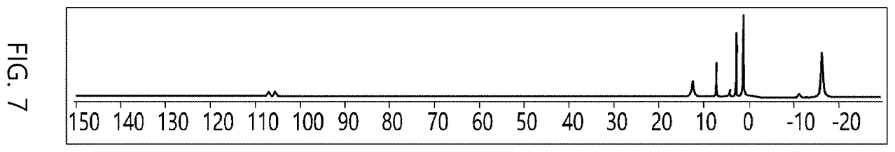

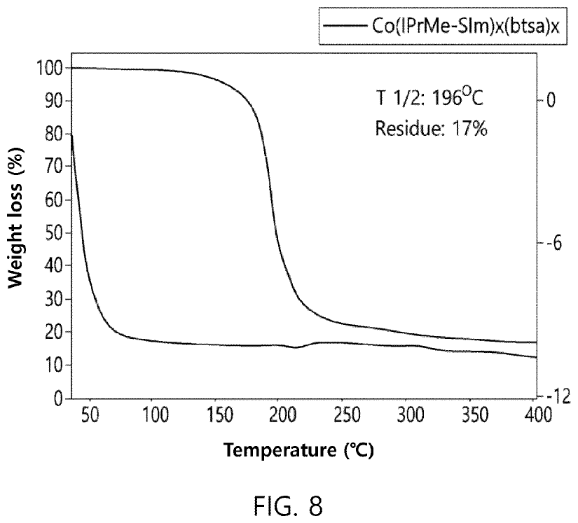

The NMR data and thermogravimetric analysis results for the compound synthesized in Example 4 are shown in FIGS. 7 and 8, respectively.

Properties of the Co(Imidazoline)(Amide) compounds synthesized in Examples 3 and 4 are summarized in Table 2 below.

TABLE 2

| | Example 3 | Example 4 |
|---|---|---|
| Compound Type | Co(MeMeSIm)₂(btsa)₂ | Co(iPrMeSIm)₂(btsa)₂ |
| Molecular Weight | 575.99 | 632.10 |
| (M.W.) | | |
| Phase | Solid | Liquid |
| Solubility | Hexane | Hexane |
| Melting Point (m.p.) | 126 | — |
| Degradation Temperature | 217 | 190 |
| (° C.) | | |
| T_{1/2} (° C.) | 215 | 196 |

T_{1/2} in Table 2 above is the temperature at which the weight is reduced by half as a result of the thermogravimetric analysis.

### Preparation Example 1: Formation of Cobalt-Containing Thin Film Using Atomic Layer Deposition (ALD)

A reaction gas including oxygen (O₂) and each of the novel cobalt precursors prepared in Examples 1 to 4 were alternatively supplied onto a substrate to form a cobalt oxide thin film. After supplying the precursor and the reaction gas, argon, a purge gas, was each independently supplied to purge residues of the precursor and the reaction gas from a deposition chamber. The supply time of the precursor was adjusted to 8 seconds to 15 seconds, and the supply time of the reaction gas was also adjusted to 8 seconds to 15 seconds. The pressure of the deposition chamber was adjusted to be in a range of 1 torr to 20 torr, and the deposition temperature was adjusted to be in a range of 80° C. to 300° C.

Most of the existing late transition metal compounds are solid compounds at room temperature and have low volatility. On the other hand, in the novel late transition metal precursor including the imidazoline ligand, according to the present disclosure, has the advantages of excellent volatility and a low melting point even in the case of being a liquid or solid compound.

In addition, using the novel precursor including the imidazoline ligand according to the present disclosure, uniform thin film deposition is enabled, and excellent thin film physical properties, thickness, and step coverage thus can be obtained.

The scope of the present disclosure is defined by the following claims rather than the description which is presented above. Furthermore, the present disclosure is intended to cover not only the exemplary embodiments, but also various alternatives, modifications, equivalents, and other embodiments that may be included within the spirit and scope of the present disclosure as defined by the appended claims.

### INDUSTRIAL APPLICABILITY

A novel compound and a precursor composition containing the novel compound, according to the present disclosure, have excellent reactivity, volatility, and thermal stability, and have a low melting point despite being liquid or solid. As a result, deposition of a uniform thin film with excellent properties is enabled, and excellent thin film physical properties, thickness, and step coverage thus can be obtained.

Such physical properties provide a late transition metal precursor suitable for atomic layer deposition and chemical vapor deposition, and contribute to excellent thin film properties.

1. A compound represented by Formula 1, 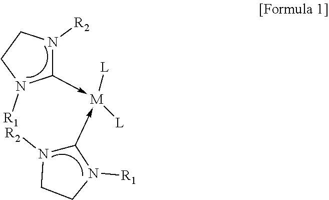
wherein in Formula 1,
M is Mn, Fe, Co, Ni, or Cu;
R₁ and R₂ are each independently hydrogen, or a straight-chain or branched-chain alkyl group having 1 to 4 carbon atoms;
L is —OR₃ or —NR₄R₅;
R₃ is hydrogen, or a straight-chain or branched-chain alkyl group having 1 to 4 carbon atoms; and
R₄ and R₅ are each independently hydrogen, a straight-chain or branched-chain alkyl group having 1 to 4 carbon atoms, or a straight-chain or branched-chain alkylsilyl group having 1 to 6 carbon atoms.

2. The compound of claim 1, wherein R₁, R₂ and R₃ are each independently any one selected from the group consisting of hydrogen, a methyl group, an ethyl group, an n-propyl group, an iso-propyl group, an n-butyl group, an iso-butyl group, a sec-butyl group, and a tert-butyl group.

3. The compound of claim 1, wherein R₄ and R₅ are each independently any one selected from the group consisting of hydrogen, a methyl group, an ethyl group, an n-propyl group, an iso-propyl group, an n-butyl group, an iso-butyl group, a sec-butyl group, a tert-butyl group, a methylsilyl group, a dimethylsilyl group, a trimethylsilyl group, and a triethylsilyl group.

4. A vapor deposition precursor composition comprising the compound of claim 1.

5. A method of forming a thin film, the method comprising introducing the vapor deposition precursor composition of claim 4 into a chamber.

6. The method of claim 5, wherein the method includes atomic layer deposition (ALD) or chemical vapor deposition (CVD).

7. The method of claim 5, further comprising injecting at least one reaction gas selected from among hydrogen (H₂), an oxygen (O) atom-containing compound, a nitrogen (N) atom-containing compound, or a silicon (Si) atom-containing compound.

8. The method of claim 7, wherein the reaction gas is at least one selected from among water (H₂O), oxygen (O₂), hydrogen (H₂), ozone (O₃), ammonia (NH₃), hydrazine (N₂H₄), or silane.

9. (canceled)
